(19) United States
(12) Patent Application Publication
(10) Pub. No.: US 2019/0012095 A1
(43) Pub. Date: Jan. 10, 2019

(54) INJECT DELAY TO SIMULATE LATENCY

(71) Applicant: Hewlett Packard Enterprise Development LP, Houston, TX (US)

(72) Inventors: Haris Volos, Palo Alto, CA (US); Guilherme de Campos MagaIhaes, Porto Alegre Rio Grande do Sul (BR); Ludmila Cherkasova, Sunnyvale, CA (US)

(21) Appl. No.: 16/065,778

(22) PCT Filed: Jan. 22, 2016
(86) PCT No.: PCT/US2016/014479

§ 371 Date: Jun. 22, 2018

(51) Int. Cl. G06F 3/06; G11C 7/22

(52) U.S. Cl. CPC G06F 3/0611; G06F 3/0659; G11C 2207/2272; G11C 7/22; G06F 3/0679

(57) ABSTRACT

Techniques for injecting a delay to simulate latency are provided. In one aspect, it may be determined that a current epoch should end. A delay may be injected. The delay may simulate the latency of non-volatile memory access during the current epoch. The current epoch may then end. A new epoch may then begin.

### BACKGROUND

New memory technologies, such as non-volatile memory hold the promise of fundamentally changing the way computing systems operate. Traditionally, memory was transient and when a memory system lost power, the contents of the memory were lost. New forms of nonvolatile memory, including resistive based memory, such as memristor or phase change memory, and other types of nonvolatile, byte addressable memory hold the promise of revolutionizing the operation of computing systems. Byte addressable non-volatile memory may retain the ability to be accessed by a processor via load and store commands, while at the same time taking on characteristics of persistence demonstrated by block devices, such as hard disks and flash drives.

### BRIEF DESCRIPTION OF THE DRAWINGS

FIG. 1 depicts an example of a system that may implement the delay injection to simulate latency techniques described herein.

FIG. 2 depicts example of computing the amount of delay to inject to simulate latency during read operations.

FIG. 3 depicts an example of determining when a delay is to be injected during read operations.

FIG. 4 depicts an example of determining a delay and injecting that delay during write a write operation.

FIG. 5 is an example of a high level flow diagram for injecting delay during read operations.

FIG. 6 is another example of a high level flow diagram for injecting delay during read operations.

FIG. 7 is an example of a high level flow diagram for injecting delay during write operations.

FIG. 8 is another example of a high level flow diagram for injecting delay during write operations.

### DETAILED DESCRIPTION

Although the new non-volatile memory technologies have the possibility to significantly alter the future of computing, those technologies are generally not ready for mainstream adoption. For example, some new memory technologies may still be experimental and are not available outside of research laboratory environments. Other technologies may be commercially available, but the current cost is too high to support wide spread adoption. Thus, a paradox arises. It is difficult to develop new software paradigms that make use of the new forms or memory without having those types of memories available for development use. At the same time, the lack of new software paradigms discourages the economic forces that would cause widespread adoption of the new memory types, resulting in greater availability of the new memory types. In other words, it is difficult to write software for new types of memory when that new type of memory is not yet available, while at the same time, there is no driving force to make that new type of memory more widely available, when there is no software capable of using the new type of memory.

Techniques described herein provide the ability to emulate the new types of memory without having to actually have the new types of memory available. A computing system may include a readily available memory. In some cases, the readily available memory may be dynamic random access memory (DRAM). Some or all of this memory may be designated to simulate non-volatile memory. One characteristic of non-volatile memory may be that the latency of non-volatile memory is greater than the latency of readily available memory, such as DRAM.

The techniques provided herein allow for injections of delays to simulate the increased latency of non-volatile memory. The amount of delay is computed in such a manner as to take into account the various different types of memory access. Furthermore, the timing of the injection of delay is such that the overhead introduced by the injection of the delay is amortized over a period of time such that the overhead does not become the dominant component of the delay. Furthermore, the injection of the delay is timed such that interdependencies between application threads are taken into account.

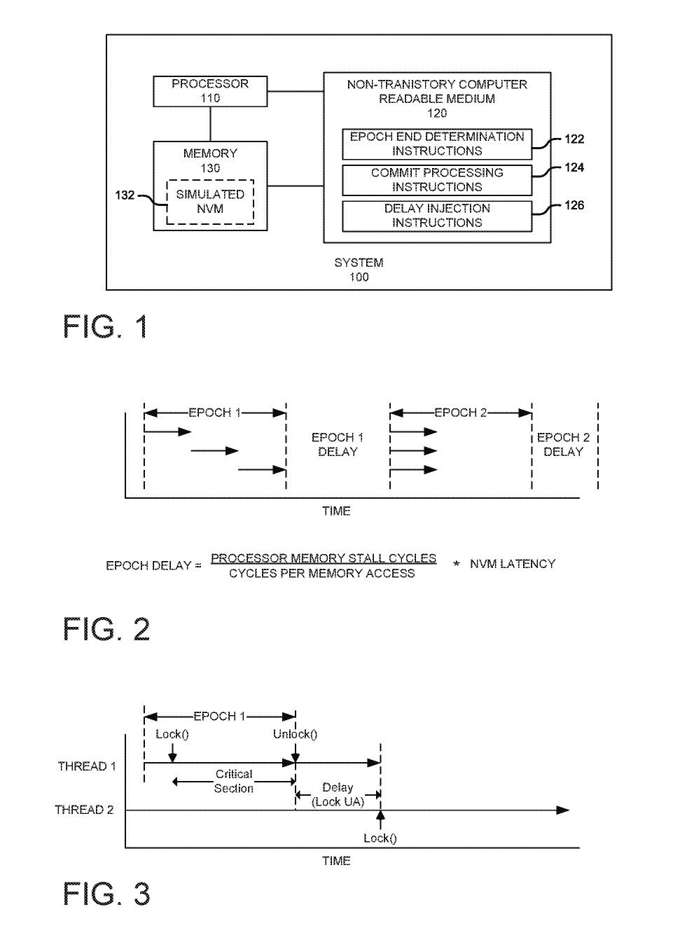

FIG. 1 depicts an example of a system that may implement the delay injection to simulate latency techniques described herein. System 100 may include a processor 110, a non-transitory computer readable medium 120, and a memory 130.

The techniques described herein are not limited to any particular type of processor. The processor 110 may be a central processing unit (CPU), graphics processing unit (GPU), application specific integrated circuit (ASIC), or any other electronic component that is capable of executing stored instructions. Furthermore, the techniques described herein are not limited to any particular processor instruction set. For example, the techniques may be used with an x86 instruction set, and ARM™ instruction set, or any other instruction set capable of execution by a processor.

Although not shown, the processor 110 may provide certain functionality, although the functionality may be implemented differently depending on the particular processor. For example, the processor may include execution units, which may also be referred to as processing cores. The execution units may be responsible for actual execution of the processor executable instructions. The processor may also include one or more caches (e.g. level 1 cache, level 2 cache, last level cache). The caches may be used to store data and/or instructions within the (as opposed being stored in memory). The processor may also include a memory controller. The memory controller may be used to load data and/or instructions from the memory 130 into the processor caches or to store data and/or instructions from the processor caches to the memory. The processor may also include performance counters. The performance counters may count certain events for purposes of tracking the performance of the processor. For example, the performance counters may count the number of processor cycles during which the processor is stalled waiting for the memory controller. The processor may also count other performance criteria, such as the number of last level cache misses experienced by the processor.

The memory 130 may be any memory suitable for use with the processor. For example, the memory may be volatile memory, such as dynamic random access memory (DRAM), static random access memory (SRAM), or any other type of byte addressable volatile memory. Some or all of the volatile memory may be designated for use as simulated non-volatile memory 132. One difference between volatile memory and real non-volatile memory may be that real non-volatile memory may have a greater latency (e.g. requires more time for read and/or write operations) than volatile memory. The techniques described herein allow for at least some of the volatile memory 130 to simulate the increased latency of non-volatile memory.

The processor 110, or more particularly, the memory controller within the processor, may communicate with the memory in fixed size units referred to as cache lines. The techniques described herein do not depend on cache lines of any given size. The size of the cache line may be defined by the processor. When a processor execution unit wishes to store a cache line from the cache to the memory 130, the cache line is sent to the memory controller. The memory controller receives the cache line (this is also referred to as being accepted by the memory), however, this does not mean the cache line has actually been written to the memory, but rather is waiting within the memory controller to be stored to the memory. The execution core need not wait for the memory controller to actually store the cache line in the memory. The execution core may also execute a commit instruction, wherein the execution cores stalls until all cache lines accepted by the memory controller have actually been written to the memory.

When the processor 110 wishes to read data from the memory 130, the request is sent to the memory controller. The memory controller schedules the read request, and will eventually read the data from the memory and store it in the processor cache.

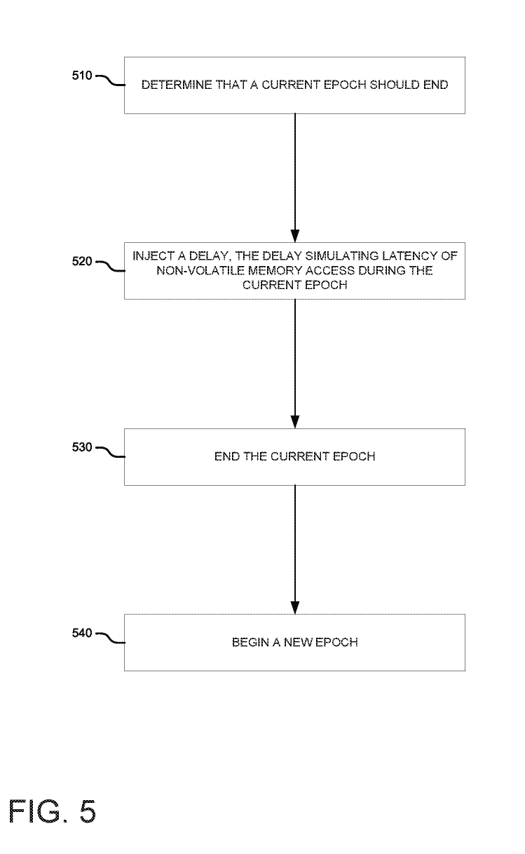

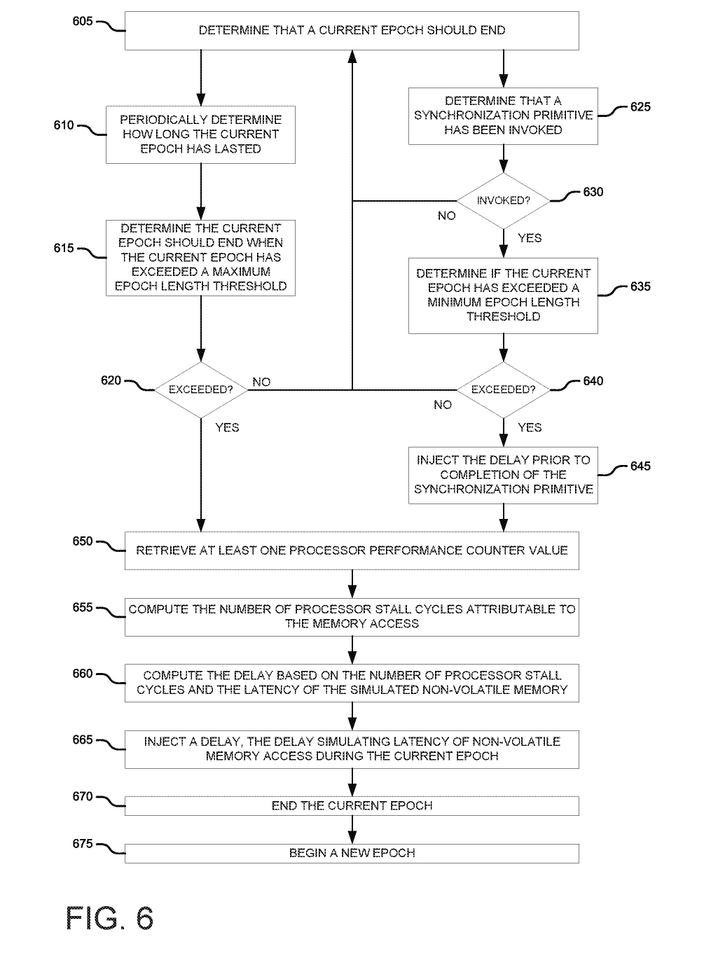

The system 100 may also include a non-transitory computer readable medium 120. The medium 120 may contain a set of instructions thereon, which when executed by the processor 110 cause the processor to implement the techniques described herein. For example, the medium may include epoch end determination instructions 122. These instructions may be used to determine when an epoch should end, and to calculate an amount of delay to insert, the delay being used to simulate the latency of non-volatile memory. Operations of instructions 122 are described further below and with respect to FIGS. 5 and 6.

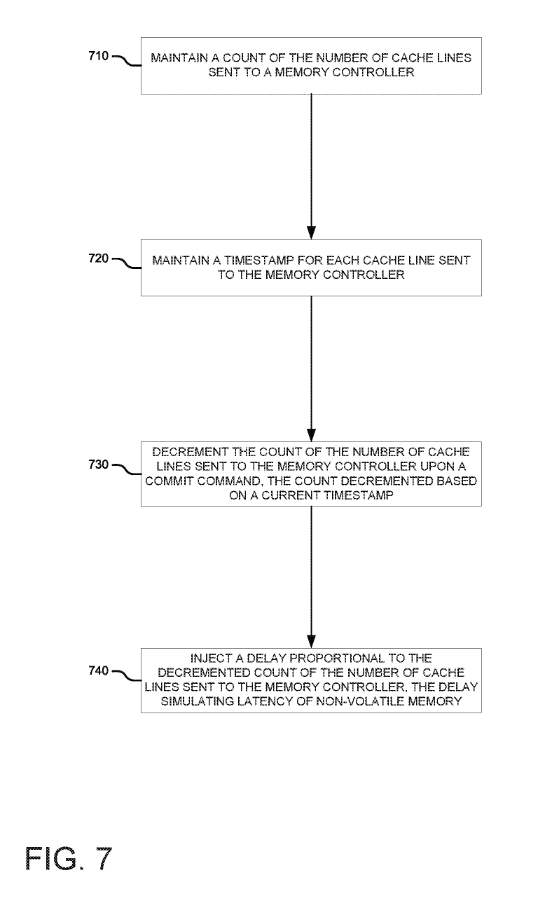

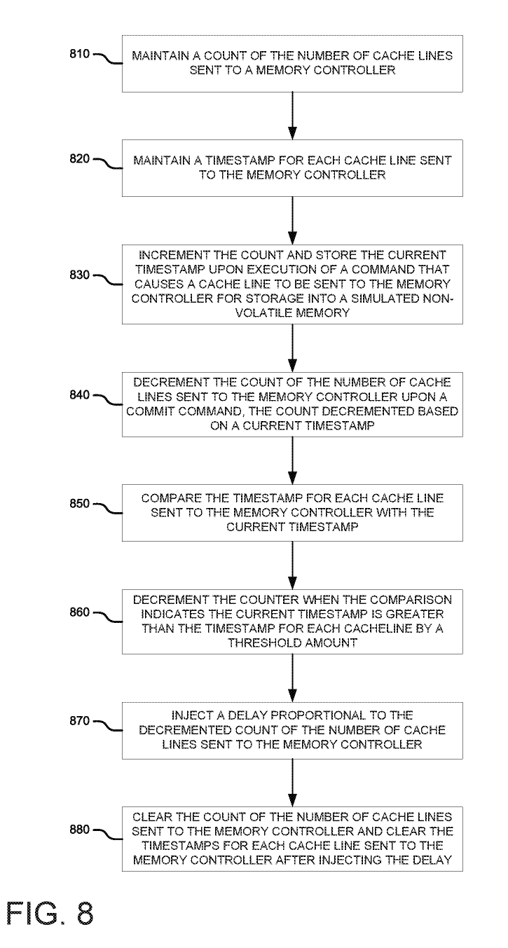

The medium 120 may also include commit processing instructions 124. The commit processing instructions may cause the processor to implement functionality related to processing a commit command. For example, the commit instructions may determine how many cache lines remain to be committed and to calculate a delay associated with the remaining number of lines. Operations of instructions 124 are described further below, and with respect to FIGS. 7 and 8.

The medium 120 may also include delay injection instructions 126. As mentioned above, an amount of delay may be calculated by epoch end determination instructions 122 and commit processing instructions 124. Those instructions may also determine when the delay should be injected. Delay injection instructions 126 may inject the computed delay in order to simulate the latency of non-volatile memory.

In operation, a user may wish to explore how an application (e.g. a thread of a software process) would behave in the presence of increased latency of non-volatile memory. The user may run the thread on system 100 in order to simulate the increased latency of non-volatile memory. As will be explained in more detail below, the processor may run the thread for a period of time, referred to as an epoch. At some point, using the epoch end determination instructions 122, the processor may determine the epoch has ended. Using the instructions 122, the processor may calculate the amount of latency that would have been experienced by the thread, had the thread been using actual non-volatile memory instead of regular memory. Using the delay injection instructions 126, the processor may inject the calculated delay, thus simulating the latency that would be experienced had real non-volatile memory been used. The determination of when an epoch should end and the calculation of the amount of delay to inject is described further below, and with respect to FIGS. 2 and 3.

The description above provides for an injection of a delay to simulate read access to memory. In order to account for the delay introduced by the increased latency from write operations, the commit processing instructions 124 may be utilized. In operation, when the processor wishes to write something to the memory, the data is sent to the memory controller portion of the processor (e.g. accepted to memory). The memory controller then stores the data in the physical memory 130. However, the actual timing of storing the data to the memory is left to the memory controller. In some cases, the application thread may wish to ensure that data being written has actually been stored to the physical memory (as opposed to just having been accepted by the memory controller).

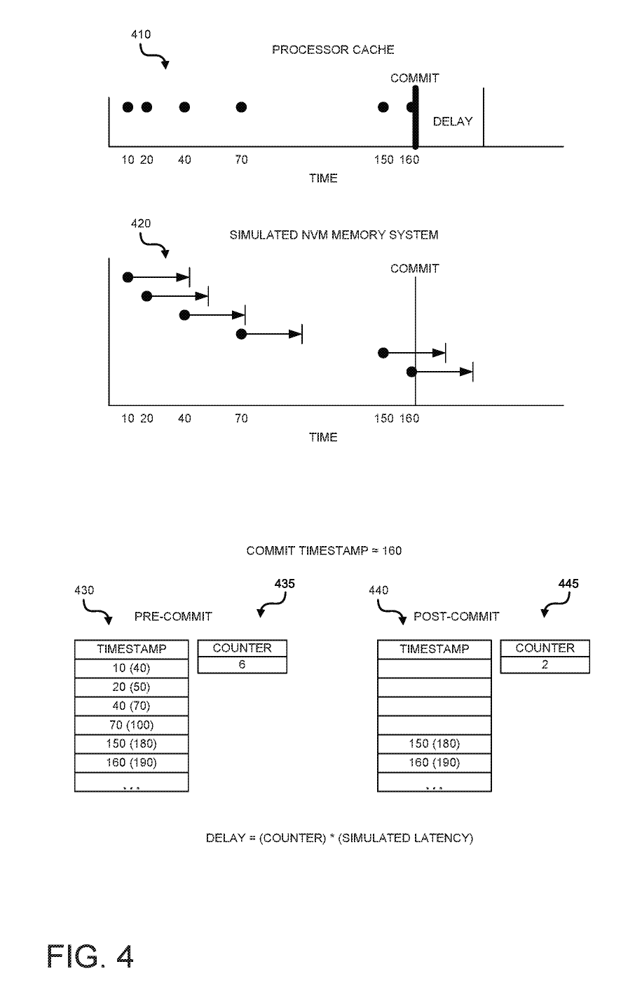

In such cases, the memory controller may execute a commit command. For example, in the x86 instruction set, a PCOMMIT command is made available. Upon execution of the commit command, the application thread may pause operation until all data that has been accepted by the memory controller has actually been stored in the physical memory 130. The instructions 124 may be used to calculate the amount of latency that would be experienced had real non-volatile memory been used. The delay injection instructions 126 may then be used to inject that delay, thus allowing the increased latency of non-volatile memory to be simulated. The calculation and injection of a delay on write operations is described in further detail below, and with respect to FIG. 4.

FIG. 2 depicts example of computing the amount of delay to inject to simulate latency during read operations. As mentioned above, the system 100 may simulate the latency that would be experienced by non-volatile memory by injecting a delay after a period of time referred to as an epoch. By injecting a delay after a period of time, instead of after each individual read instruction, the overhead of injecting the delay is amortized over the entire epoch. By amortizing the overhead over the entire epoch, the contribution of delay from the injection overhead can be reduced, allowing for the computed delay (e.g. the delay attributable to the increased latency of non-volatile memory) to be the main component.

One naïve approach to computing the delay may be to simply take the number of memory accesses and multiply that number by the expected latency increase for non-volatile memory. It should be noted that the computed delay is the expected increase in latency over normal memory (e.g. DRAM), not the expected latency of non-volatile memory. The reason being that the system 100 is operating with real memory, such as DRAM, so the actual latency caused by the DRAM is still experienced by the application thread. Epoch 1 in FIG. 2 shows three memory accesses, designated by three arrows. If the memory accesses are sequential, as shown in Epoch 1, the naïve approach would be acceptable. In other words, the increased latency of simulated non-volatile memory for each memory access could be added together, and then injected at the end of the epoch.

However, most current computing systems are not limited to sequential memory access. Epoch 2 shown in FIG. 2 again depicts three memory accesses as arrows. However, in epoch 2, the memory accesses occur in parallel. As should be clear, if the expected latency for each of these three accesses were simply added, the total would be three times to large. The reason being that the latency experienced by the application thread for these three memory accesses would occur in parallel, not sequentially.

The techniques described herein overcome this problem by computing the delay based on the amount of time the processor spends waiting for the memory controller system. For example, the processor may maintain a count of the number of processor stall cycles that were experienced by the processor while waiting for the memory system. The number of stall cycles may then be converted to a number of memory accesses by dividing the number of stall cycles by the latency experienced by the memory (e.g. the real memory). Once the number of memory accesses that actually caused the processor to stall has been determined, that number of access can be multiplied by the expected latency of the non-volatile memory.

As shown in FIG. 2, the epoch delay may be computed by dividing the processor memory stall cycles by the cycles per memory access to give the number of memory accesses that caused processor stalls. The number of memory access is multiplied the expected latency of non-volatile memory to determine the amount of delay to inject. For example, assume the processor was stalled for 100 cycles waiting for memory, and the latency of the real memory is 2 cycles (i.e. 100/2). Thus it can be computed that there were virtually 50 sequential memory accesses. If the expected latency of non-volatile memory is 10 cycles, it can be computed that 50 memory accesses would cause 500 cycles of delay (e.g. 50*10). Considering the actual memory latency is 2 cycles, each sequential memory access must be increased by 8 cycles. Thus a delay of 400 cycles (50*(10−2)) could be injected.

It should be understood that the techniques described herein are not dependent on any particular counter for determining the number of stall cycles caused by the memory system. For example, although many processors may include a counter such as the one described above, in some processor implementations, the counter may not be reliable. However, the data may still be obtained by using other performance counters. For example, many processors include a counter to determine the number of processor stall cycles caused by waiting for a data transfer from a last level cache. In other words the processor counts how long it is waiting for data to be loaded from memory.

The processor may also maintain a count of how many last level cache accesses result in a cache hit (e.g. cache line found in last level cache, no memory access needed) as well as a count of cache misses (e.g. cache line not found is last level cache, memory access needed). Thus, the percentage of access to the last level cache access resulting in a cache miss can be computed (e.g. last level cache miss/(last level cache hit+last level cache miss)). If this percentage is multiplied by the number of processor cycles spent waiting for the last level cache, it can be determined how many cycles were spent waiting on access to the memory system (e.g. cycles spent waiting for last level cache *% of those cycles that needed to access physical memory). It should be understood that the techniques described herein may utilize any available performance counters to compute the number of processor cycles spent waiting for the memory system.

FIG. 3 depicts an example of determining when a delay is to be injected during read operations. In FIG. 2, calculating the amount of delay to insert at the end of an epoch was described, FIG. 3 describes how to determine when an epoch should end and when the delay should be injected. In a simple case, epochs could be of fixed length, and the delay could be injected at the end of the epoch. For example, a monitor thread could be created that periodically sends a signal to the application thread to interrupt the application thread. The application thread could determine how long the current epoch has lasted (e.g. by comparing a timestamp of when the epoch began vs a current timestamp). If the current epoch has lasted for a period that exceeds a threshold, the epoch can be ended, a delay injected, and a new epoch begun. The techniques described herein may use this technique.

However, using solely the fixed epoch length technique described above may lead to problems, in particular with respect to multi-threaded applications. For example, assume an application has two threads that share a resource. Assume that there is a lock structure that each thread acquires when using the resource, the lock preventing the other thread for accessing the resource. If the first thread holds the lock, and the second thread is waiting for it, the second thread will begin running as soon as the lock is released. Thus, unless the end of the epoch absolutely correlates with the time the lock is released by the first thread, the second thread will be allowed to run without having experienced the injected delay. Even if the epoch were to end at the same time the lock is released, the second thread would still be allowed to as soon as the lock became available, and as such would not experience the injected delay.

The techniques described herein overcome these problems by first causing the current epoch of a thread to end upon any execution of a synchronization primitive. Here, a synchronization primitive is the execution of any set of instructions in one thread that may affect a different thread. As explained above, the acquiring/releasing of a lock on a resource shared between two threads would be an example of a synchronization primitive. In addition, any call to a synchronization primitive is not allowed to complete until after the delay is injected. Although a lock has been mentioned as a synchronization primitive, it should be understood that the techniques described herein are not some limited. What should be understood is that upon execution of any synchronization primitive by a thread, the current epoch of that thread is ended. Furthermore, the synchronization primitive is modified such that the delay is injected prior to any other thread being allowed to proceed.

FIG. 3 depicts two threads of an application program that may share a resource, the resource protected by a lock that can only be held by one thread at a time. For example, as shown, the resource may be a “critical section” of code that can only be used by one thread at a time. It should be understood that the term “Critical Section” is being used as a computer science term of art, and is not intended to imply that the section of code is any more or less important than any other section of code. Rather, it simply means the section of code can only be executed by one thread at a time.

At some point during thread 1 epoch 1 (it should be understood that epochs are thread specific, and need not align between multiple threads), thread 1 may take a lock to a critical section of code, as depicted by the call to the lock( ) primitive. Thread 1 may then execute this code exclusively. At some point, thread 2 may wish to execute the same critical section of code, but cannot do so while thread 1 holds the lock. At some point, thread 1 may be finished with the critical section of code, and releases the lock, as designated by the call to the Unlock( ) primitive. The techniques described herein may modify the unlock primitive, such that the call does not complete until after the injection of the delay (the amount of delay can be computed as described above). This period is shown as the Delay (Lock UA), where the delay is injected and the lock is unavailable to the second thread.

After the delay is complete, the unlock primitive completes, and the lock becomes available again. In other words, the lock does not become available for use by any other thread until after injection of the delay has been completed. When thread 2 is able to acquire the lock, the delay attributable to memory access during the critical section has already been injected. Thus, thread 2 is not able to being execution until after the delay attributable to execution of the critical section by thread 1 has been injected. This prevents thread 2 from beginning execution early by not allowing an overlap between the period of delay injection and acquiring the lock by thread 2. In other words, from the perspective of the second thread, the first thread was operating with non-volatile memory. It should further be noted, that in some cases, the period of time that a thread holds a lock is of such a small duration, that the overhead of waiting until the delay is injected prior to completing the synchronization primitive is not worth it. In some implementations, a minimum epoch length threshold may also be implemented. A minimum epoch length threshold may ensure the epoch length is sufficiently long such that the overhead of injecting the delay does not eclipse the amount of the delay that is actually being injected.

FIG. 4 depicts an example of determining a delay and injecting that delay during a write operation. The description thus far has focused on injecting delays for purposes of simulating the latency caused by non-volatile memory in the context of read operations. However, the latency of non-volatile memory is also experienced in the context of write operations. The memory controller operates differently with respect to write operations and the epoch based mechanism described above may not be suitable.

For example, the execution cores of the processor send cache lines to the memory controller to be written to the memory. The memory controller receives these cache lines (e.g, the lines are accepted to memory) but this does not mean the lines are actually written to the physical memory. Instead, the memory controller, using its own scheduling and prioritization, determines when the received cache lines are actually written to the physical memory.

The processor may provide certain commands that cause cache lines to be sent to the memory controller for writing to the memory. For example, in the x86 instruction set, the cache line write back (CLWB) command may be provided to cause a cache line to be sent to the memory controller. Another example of such a command is the cache line flush (CLFLUSH) command, which also causes a cache line to be sent to the memory controller.

Even though the cache lines are sent to the memory controller, then are not immediately sent to the memory. The processor may continue to execute the thread while the cache lines remain within the memory controller. The processor may also provide a commit command. For example, in the x86 instruction set, the processor provides the PCOMMIT command. Upon execution of a commit command, the processor may pause execution of the thread until all cache lines sent to the memory controller by that thread have actually been written to the memory.

The latency of writing to non-volatile memory is likely greater than the latency of writing to volatile memory. To simulate this latency, the techniques described herein inject an additional delay to simulate the increased latency of non-volatile memory. The techniques described herein keep track of the time when a cache line is sent to the memory controller. In other words, the time when a CLWB or CLFUSH type command is executed. When a commit command is executed, the current timestamp is examined and compared to the timestamp of each received cache line. If the timestamps differ by an amount greater than the expected latency of writing to non-volatile memory, those lines can be treated as having already been written to the simulated non-volatile memory. However, if the timestamp is less than this threshold amount, the cache line can be considered as not yet having been written to the memory. Thus, a delay is introduced that is proportional to the number of cache lines that have not yet been written to the memory.

For purposes of description of FIG. 4, assume that the expected latency of a write to non-volatile memory is 30 units. As shown in the top graph 410, each dot represents a cache line being sent to the memory controller for eventual writing to the memory. As shown, cache lines are sent at time 10, 20, 40, 70, 150, and 160.

The second graph 420 shows the same cache lines and their expected time of completion if the system was using non-volatile memory. For example, if a cache line was received by the memory controller at time 10, and the latency of non-volatile memory is 30 units, it would be expected that the cache line received at time 10 would have been written to the memory by time 40. The period of latency is depicted by the short arrow terminating in a vertical line for each cache line. At some point, such as at time 160 shown in FIG. 4, a commit command may be executed. At this point, the processor may pause the application thread until all cache lines have been written to memory.

As shown in table 430, the system may keep track of the time each cache line is received by the memory controller. As shown, the timestamp for each cache line is shown. In addition, the system may determine when the cache line would be expected to be written to memory, assuming the latency of non-volatile memory (e.g. the number in parenthesis). For example, the third entry in table 430 shows a cache line received at time 40. Assuming a 30 unit latency for writing to non-volatile memory, the cache line can be expected to be written to memory by timestamp 70. In addition, as each cache line is received, the system may maintain a counter 435, indicating how many cache lines total have been received.

At some point, a commit command may be executed. As shown, the commit command is executed at time stamp 160. The system may then compare the time stamp of each received cacheline (as shown in table 430) to the current timestamp (e.g. 160). For cache lines that would have completed by the current timestamp (e.g. those lines which have a number in parenthesis in table 435 that is less than the current time stamp) the entry in the table may be cleared, and the counter decremented. Table 440 depicts table 430 after the commit command has been executed at time 160. Thus all entries expected to have completed by time 160 have been removed. Likewise, counter 445 is decremented for each entry removed from table 430 and now indicates the number of cache lines remaining. The number of cache lines remaining (e.g. the counter) may then be multiplied by the expected latency of non-volatile memory to calculate the amount of delay to be inserted.

FIG. 5 is an example of a high level flow diagram for injecting delay during read operations. In block 510, it may be determined that a current epoch should end. As explained above, and in further detail below, an epoch may end for multiple reasons. An epoch may end upon reaching a maximum epoch length threshold. An epoch may also end upon execution of a synchronization primitive. In block 520, a delay may be injected. The delay may simulate the latency of non-volatile memory access during the current epoch. In other words, the memory used by the system may have a latency that is less than the latency expected from non-volatile memory. By injecting an additional delay, the overall latency may be increased. By selecting the additional delay to correspond to the increased latency of non-volatile memory, the latency of non-volatile memory can be simulated. In block 530, the current epoch may be ended. In block 540, a new epoch may begin.

FIG. 6 is another example of a high level flow diagram for injecting delay during read operations. In block 605, as above, it may be determined that a current epoch should end. In one mechanism for making such a determination, the process may move to block 610. In block 610, it may be periodically determined how long the current epoch has lasted. For example, in one implementation, a process thread may be interrupted periodically, and upon being interrupted, the process thread may determine how long the current epoch has lasted. For example, in an implementation, a monitor thread may be spawned that periodically sends a signal to the process thread in question.

Upon receipt of the signal, the process thread may examine a current timestamp (e.g. a current processor timestamp) and compare that timestamp with a timestamp that was set when the epoch began. This comparison may be used to determine how long the current epoch has lasted. In block 615, it may be determined that the current epoch should end when the current epoch has exceeded a maximum epoch length threshold. Continuing with the example implementation, when the timestamp comparisons indicate the current epoch has lasted longer than the maximum allowable epoch length, it may be determined that the epoch should end. It should be understood that the techniques described herein are not limited to any particular maximum length of an epoch and any length is suitable. In block 620, if the maximum epoch length has not been exceeded, the process returns to block 605. Otherwise, the process moves to block 650, which is described further below.

In another mechanism for making a determination that the current epoch should end, the process may move to block 625. In block 625, it may be determined that a synchronization primitive has been invoked. As explained above, synchronization primitives may be used to coordinate between different threads of execution. The execution of a synchronization primitive may allow a thread that was previously suspended because it was waiting for a resource that was busy to begin execution. In block 630, if no synchronization primitive has been invoked, the process returns to block 605.

If a synchronization primitive has been invoked, the process moves to block 635. In block 635, it may be determined if the current epoch has exceeded a minimum epoch length threshold. In some cases, the overhead involved with injecting a delay may be excessive given the length of time the current epoch has lived. As such, it may not make sense to inject a delay when the epoch has only lasted for a time period less than the minimum epoch length threshold. However, it should be understood that the techniques described herein are not limited to any particular minimum epoch length threshold, and any minimum length (including no minimum length) may be suitable.

In block 640, if the minimum epoch length threshold is not exceeded, the process moves back to block 605. Otherwise, the process moves to block 645. In block 645, the delay is injected prior to completion of the synchronization primitive. Block 645 is not intended to depict the insertion of the actual delay, but rather indicates that the synchronization primitive is not completed until after the delay is injected. As was explained above with respect to FIG. 3, delaying completion of the synchronization primitive until after the delay has been injected ensures that a thread that is waiting for a resource does not begin execution until after the simulated delay for non-volatile memory has been injected.

In block 650, at least one processor performance counter value may be retrieved. As explained above, processors may maintain various performance counters. Using one or more of these counter values, the system described herein may determine the proper amount of delay to inject. In block 655, the number of processor stall cycle attributable to memory access may be computed. As explained above, the number of processor cycles that are spent waiting for the memory system of the processor to retrieve data from memory can be determined based on the performance counters.

In block 660, the delay may be computed based on the number of processor stall cycles and the latency of the simulated non-volatile memory. In other words, it may be determined how many cycles were spent by the processor waiting for access to the memory of the system described herein (e.g. the real memory). For example, if 100 cycles were spent waiting, and access to the real memory takes 2 cycles, it can be determined that there were 50 memory accesses that needed to wait for the memory system to retrieve data from the real memory. To simulate the latency of non-volatile memory (which is likely greater than the memory included in the system) an additional delay may be inserted. For example, if it is assumed that the latency of non-volatile memory is 10 cycles per access, and 2 cycles were spent waiting for the real memory access, an additional 8 cycles per memory access is needed to simulate non-volatile memory. In the current example, it has been determined that there were 50 memory accesses. As such, the additional delay required is 50*8=400 cycles.

In block 665, a delay may be injected. The delay may simulated the latency of non-volatile memory access during the current epoch. For example, according to the previous example, a delay of 400 cycles may be injected. This additional delay would simulate the latency of non-volatile memory had the system actually been equipped with non-volatile memory. In block 670, the current epoch may be ended. As part of ending the current epoch, the performance counters used to determine the number of stall cycles the processor experienced by the processor waiting for the memory system may be reset. In block 675, a new epoch may begin.

FIG. 7 is an example of a high level flow diagram for injecting delay during write operations. In block 710, a count may be maintained of the number of cache lines sent to a memory controller. As explained above, as cache lines are to be written to the memory of the system, those lines are sent to the memory controller of the processor. Although the memory controller may accept the cache lines, they may not be immediately written to the memory. The count that is maintained may be the number of cache lines sent to the memory controller, independent of if those lines have actually been written to the memory.

In block 720, a timestamp may be maintained for each cache line sent to the memory controller. In other words, as cache lines are sent to the memory controller, the time at which each line is sent to the memory controller may be recorded. For example, the timestamps may be recorded in a table, as shown in FIG. 4.

In block 730, upon a commit command the count of cache lines sent to the memory controller may be decremented. As will be explained in further detail below, the count may be decremented based on the current timestamp. For example, the count may be decremented once for each cacheline whose recorded timestamp exceeds the current timestamp by a defined amount.

In block 740, a delay may be injected. The delay may be proportional to the decremented count of the number of cache lines sent to the memory controller. The delay may simulate latency of non-volatile memory. As will be explained in further detail below, the injected delay may simulate the delay of the latency of non-volatile memory for those cache lines that have not yet been written to the memory.

FIG. 8 is another example of a high level flow diagram for injecting delay during write operations. In block 810, just as above in block 710, a count may be maintained of the number of cache lines sent to a memory controller. In block 820, just as in block 720, a timestamp may be maintained for each cache line sent to the memory controller.

In block 830, the count may be incremented and the current timestamped stored upon execution of a command that causes a cache line to be sent to the memory controller for storage into a simulated non-volatile memory. As explained above, such commands may include a cache line write back (CLWB) or cache line flush (CLFLUSH) command. However, it should be understood that the techniques described herein are not limited to those particular commands. Rather, the techniques are applicable with any processor instructions that causes a cache line to be sent to the memory controller to eventually be written to the real memory.

In block 840, the count of the number of cache lines sent to the memory controller may be decremented upon a commit command. The count may be decremented based on a current timestamp. As explained above, a commit command may include a command such as PCOMMIT, although the techniques described herein are not limited to any specific command. It should be understood that a commit command is any command that causes the processor to halt execution of a thread until all cache line write requests that have been sent to the memory controller have been completed and those cache lines have been stored within the memory. The current timestamp may be used, as described with respect to FIG. 4, to determine which cache lines sent to the memory controller have already been written to the simulated non-volatile memory, as will be described in further detail below.

In block 850, the timestamp for each cache line sent to the memory controller may be compared with the current timestamp. It should be understood that such a comparison may be used to determine how much time has passed since the cache line was originally sent to the memory controller. In some implementations, the cache lines may be grouped, with only the latest timestamp stored for purposes of simplification and storage optimization. In block 860, the counter may be decremented when the comparison indicates the current timestamp is greater than the timestamp for each cache line by a threshold amount. For example, if the cache line was received at the memory controller at timestamp 10, and the threshold is 30 time units, the count will be decremented if the current timestamp is 40 or greater (i.e. 10+30=40). If the current timestamp was less than 40, the count would not be decremented.

As explained above, the threshold may be set to reflect the expected delay of simulated non-volatile memory. If the current timestamp exceeds the timestamp of when the cache line was received by the threshold amount, it may be assumed the cache line has already been written to the memory. However, in the opposite case, it can be assumed that the cache line has not yet been written, and as such, the latency of the simulated non-volatile memory has not yet been taken into account.

In block 870, a delay proportional to the decremented count of the number of cache lined sent to the memory controller may be injected. As explained above, after the decrementing of the counter for cache lines that have had sufficient time (taking into account the latency of the simulated non-volatile memory) to be sent from the memory controller to the memory, the counter then reflects the number of cache lines that remain to be sent to the simulated non-volatile memory. In the boundary case (wherein a cache line is sent to the memory controller and a commit command is executed immediately thereafter), it can be assumed that the cacheline would be written to the memory within the threshold time period. Thus, by injecting a delay proportional to the number of cache lines remaining to be sent to the memory, the delay for cache lines remaining to be written to the memory can be taken into account. In block 880, the count of the number of cache lines sent to the memory controller and the time stamps for each cache line sent to the memory controller may be cleared after injecting the delay.

We claim:

1. A non-transitory processor readable medium containing instructions thereon which when executed by a processor cause the processor to:
determine that a current epoch should end;
inject a delay, the delay simulating latency of non-volatile memory access during the current epoch;
end the current epoch; and
begin a new epoch.

2. The medium of claim 1, wherein determining that the current epoch should end further comprises instructions to:
periodically determine how long the current epoch has lasted; and
determine the current epoch should end when the current epoch has exceeded a maximum epoch length threshold.

3. The medium of claim 1, wherein determining that the current epoch should end further comprises instructions to;
determine that a synchronization primitive has been invoked; and
injecting the delay prior to completion of the synchronization primitive.

4. The medium of claim 3, wherein determining that the current epoch should end further comprises instructions to:
determine that a synchronization primitive has been invoked;
determine if the current epoch has exceeded a minimum epoch length threshold; and
injecting the delay prior to completion of the synchronization primitive when the minimum epoch length threshold has been exceeded.

5. The medium of claim 1, wherein injecting a delay further comprises instructions to;
determine a number of processor stall cycles attributable to memory access; and
compute the delay based on the number of processor stall cycles and the latency of the simulated non-volatile memory.

6. The medium of claim 5 wherein determining the number of processor stall cycles comprises instructions to:
retrieve at least one processor performance counter value; and
compute the number of processor stall cycles attributable to the memory access.

7. A non-transitory processor readable medium containing instructions thereon which when executed by a processor cause the processor to:
maintain a count of the number of cache lines sent to a memory controller;
maintain a timestamp for each cache line sent to the memory controller;
decrement the count of the number of cache lines sent to the memory controller upon a commit command, the count decremented based on a current timestamp; and
inject a delay proportional to the decremented count of the number of cache lines sent to the memory controller, the delay simulating latency of non-volatile memory.

8. The medium of claim 7 wherein maintaining the count and timestamp for each cacheline comprises instructions to:
increment the count and store the current timestamp upon execution of a command that causes a cache line to be sent to the memory controller for storage into a simulated non-volatile memory.

9. The medium of claim 7 wherein decrementing the count based upon the commit command comprises instructions to:
compare the timestamp for each cache line sent to the memory controller with the current timestamp; and
decrement the counter when the comparison indicates the current timestamp is greater than the timestamp for each cacheline by a threshold amount.

10. The medium of claim 9 wherein the threshold amount is a simulated latency of non-volatile memory.

11. The medium of claim 9 wherein the comparison begins with the most recent timestamp of a cache line sent to the memory controller.

12. The medium of claim 9 further comprising instructions to:
clear the count of the number of cache lines sent to the memory controller and clear the timestamps for each cache line sent to the memory controller after injecting the delay.

13. A system comprising:
a processor; and
a memory coupled to the processor, the memory containing instructions which when executed by the processor cause the processor to:
determine an epoch should end, the determination based upon a thread completing a critical section; and
inject a delay, the delay simulating a latency of non-volatile memory reads, prior to ending the epoch.

14. The system of claim 13 further comprising instructions to:
determine a number of cache lines accepted by a memory system of the processor that have not yet been committed to memory; and
inject a delay based on the determined number of cache lines.

15. The system of claim 13 wherein the delay is based on a number of processor stall cycles attributable to memory loads.
